(19) United States
(12) Patent Application Publication
(10) Pub. No.: US 2026/0269182 A1
(43) Pub. Date: Sep. 10, 2026

(54) SYSTEM AND METHOD FOR ADJUSTING AN ION BEAM

(71) Applicant: Applied Materials, Inc., Santa Clara, CA (US)

(72) Inventor: Eric Donald Wilson, Rockport, MA (US)

(73) Assignee: Applied Materials, Inc., Santa Clara, CA (US)

(21) Appl. No.: 19/069,402

(22) Filed: Mar. 4, 2025

(51) Int. Cl. H01J 37/317; H01J 37/12; H01J 37/147; H01J 37/304

(52) U.S. Cl. CPC H01J 37/3171; H01J 37/12; H01J 37/1477; H01J 37/3045; H01J 2237/20228; H01J 2237/24528; H01J 2237/24578

(57) ABSTRACT

Ion beam implantation systems, devices, and methods for adjusting an ion beam. An ion beam implantation system includes a shutter component configured to adjust an ion beam received from an ion beam source and being incident on a wafer plane. The system includes a controller component communicatively coupled to the shutter component. The controller is configured to receive an ion beam implantation recipe and change a size of an aperture of the shutter component based the ion beam implantation recipe and one or more measurements of the ion beam.

### TECHNICAL FIELD

This disclosure generally relates to ion beam implantation systems, and in particular, to adjusting beam shape in ion beam implantation systems.

### BACKGROUND

Ion beam implantation systems are advanced tools used in semiconductor manufacturing to modify various properties of materials by embedding ions into a substrate. Typically, such processes involve acceleration of ions to high energies and directing them into the target material, e.g., silicon wafers, to alter electrical, physical, and/or chemical properties. The ion beam implantation systems are designed to control doping levels in semiconductors, which is important for fabrication of integrated circuits and/or other electronic devices. The processes performed by the ion beam implantation systems are defined by ion implantation process recipes that define specifics of the processes and are provided to the system's controller components prior to implantations.

Some ion implantation process recipes require tight control of spot beam shapes, produced by the existing ion beam implantation systems, as well as vertical centering prior to being electrostatically scanned onto wafer planes. For example, if the spot beam is too tall and/or is vertically off-center, it could scrape the top and/or bottom of a beamline during implantation. Such beam-scrape can result in an unstable, non-uniform ion beam densities across the wafer planes and reduce resulting device's performance and yield (DPY). Moreover, while existing systems are capable of performing adjustments to the ion beams, such adjustments are typically slow and may be inaccurate.

### SUMMARY

In some implementations, the current subject matter relates to an ion beam implantation system that may include a shutter component configured to adjust an ion beam received from an ion beam source and being incident on a wafer plane, and a controller component communicatively coupled to the shutter component. The controller component may be configured to receive an ion beam implantation recipe and change a size of an aperture of the shutter component based the ion beam implantation recipe and one or more measurements of the ion beam.

In some implementations, the current subject matter may include one or more of the following optional features. The ion beam implantation recipe may include a minimum size of the aperture. The shutter component may include a first aperture limiting portion and a second aperture limiting portion. The controller component may be configured to cause the shutter component to reduce the size of the aperture by moving the first and second aperture limiting portions closer together or increase the size of the aperture by moving the first and second aperture limiting portions apart from one another. One or more measurements may include a location of the ion beam on the wafer plane. The system may also include an electrostatic lens component and a dipole magnet component coupled to the controller component. The controller component may be configured to vertically center the ion beam on the wafer plane by reducing, using the shutter component, the size of the aperture in accordance with the minimum size of the aperture and adjusting the ion beam by changing a vertical position of the ion beam to vertically center the ion beam on the wafer plane using at least one of: a Y-axis component of the electrostatic lens component, the dipole magnet component, and any combination thereof, wherein the changing of the vertical position is limited by the reduced size of the aperture. A vertical center of the ion beam on the wafer plane corresponds to a peak current of the ion beam generated in response to the adjusting performed by at least one of: the Y-axis component of the electrostatic lens component, the dipole magnet component, and any combination thereof. The Y-axis component of the electrostatic lens component and the dipole magnet component may be configured to change the vertical position of the ion beam along a Y-direction of the ion beam by varying a respective position of the Y-axis component of the electrostatic lens component and a current of the dipole magnet component.

In some implementations, one or more measurements may include a height of the ion beam on the wafer plane. Adjusting the ion beam may include reducing the height of the ion beam on the wafer plane.

In some implementations, the system may include an electrostatic lens component coupled to the controller component. The controller component may be configured to reduce height of the ion beam on the wafer plane by reducing, using the shutter component, the size of the aperture in accordance with the minimum size of the aperture and adjusting the ion beam by changing the height of the ion beam along a Z-direction of the ion beam on the wafer plane using a Z-axis component of the electrostatic lens component, wherein the changing of the height of the ion beam along the Z-direction is limited by the reduced size of the aperture. The changed height of the ion beam along the Z-direction of the ion beam on the wafer plane may correspond to a peak current of the ion beam generated in response to the adjusting performed by the Z-axis component of the electrostatic lens component.

In some implementations, the system may include a focus voltage component coupled to the controller component. The controller component may be configured to reduce height of the ion beam on the wafer plane by reducing, using the shutter component, the size of the aperture in accordance with the minimum size of the aperture and adjusting the ion beam by changing the height of the ion beam by changing a focus voltage using the focus voltage component of the electrostatic lens component, wherein the changing of the height of the ion beam is limited by the reduced size of the aperture. The changed height of the ion beam on the wafer plane may correspond to a peak current of the ion beam generated in response to the adjusting performed by the focus voltage component of the electrostatic lens component.

In some implementations, the system may include a scan offset electrostatic lens component and a post scan offset electrostatic lens coupled to the controller component. The controller component may be configured to reduce height of the ion beam on the wafer plane by reducing, using the shutter component, the size of the aperture in accordance with the minimum size of the aperture and adjust the ion beam by changing the height of the ion beam on the wafer plane using at least one of: the scan offset electrostatic lens component, the post scan offset electrostatic lens, and any combination thereof, wherein the changing of the height of the ion beam may be limited by the reduced size of the aperture. The height position of the ion beam on the wafer plane may correspond to a peak current of the ion beam generated in response to the adjusting performed by at least one of: the scan offset electrostatic lens component, the post scan offset electrostatic lens, and any combination thereof.

In some implementations, adjusting the ion beam may include increasing the height of the ion beam on the wafer plane. The system may include a quadrupole magnet component coupled to the controller component. The controller component may be configured to increase height of the ion beam on the wafer plane by reducing, using the shutter component, the size of the aperture in accordance with the minimum size of the aperture and adjusting the ion beam by increasing the height of and reducing a width of the ion beam on the wafer plane using the quadrupole magnet component, wherein the increasing the height of and the reducing the width of the ion beam on the wafer plane may be limited by the reduced size of the aperture. The increased height of the ion beam on the wafer plane may correspond to a peak current of the ion beam generated in response to the adjusting performed by the quadrupole magnet component.

In some implementations, the current subject matter relates to a method that may include receiving, using a controller component of an ion beam implantation system, an ion beam implantation recipe, the ion beam implantation system including an ion beam source configured to generate an ion beam, the ion beam being incident on a wafer plane, a shutter component, and the controller component communicatively coupled to the shutter component; changing, using the controller component, a size of an aperture of the shutter component based the ion beam implantation recipe and one or more measurements of the ion beam, and adjusting, using the controller component, the ion beam received from the ion beam source.

In some implementations, the current subject matter may include one or more of the following optional features. The ion beam implantation recipe may include a minimum size of the aperture. The shutter component may include a first aperture limiting portion and a second aperture limiting portion. The method may include using controller component to cause the shutter component to reduce the size of the aperture by moving the first and second aperture limiting portions closer together, or increase the size of the aperture by moving the first and second aperture limiting portions apart from one another. One or more measurements include a location of the ion beam on the wafer plane. The ion beam implantation system may include an electrostatic lens component and a dipole magnet component coupled to the controller component. The method may include vertically centering, using the controller component, the ion beam on the wafer plane by reducing, using the shutter component, the size of the aperture in accordance with the minimum size of the aperture and adjusting the ion beam by changing a vertical position of the ion beam to vertically center the ion beam on the wafer plane using at least one of: a Y-axis component of the electrostatic lens component, the dipole magnet component, and any combination thereof, wherein the changing of the vertical position is limited by the reduced size of the aperture. A vertical center of the ion beam on the wafer plane may correspond to a peak current of the ion beam generated in response to the adjusting performed by at least one of: the Y-axis component of the electrostatic lens component, the dipole magnet component, and any combination thereof. The method may also include changing, using the electrostatic lens component and the dipole magnet component, the vertical position of the ion beam along a Y-direction of the ion beam by varying a respective position of the Y-axis component of the electrostatic lens component and a current of the dipole magnet component. One or more measurements may include a height of the ion beam on the wafer plane. Adjusting the ion beam may include reducing the height of the ion beam on the wafer plane. The ion beam implantation system may include an electrostatic lens component coupled to the controller component. The method may include reducing, using the controller component, the height of the ion beam on the wafer plane by reducing, using the shutter component, the size of the aperture in accordance with the minimum size of the aperture and adjusting the ion beam by changing the height of the ion beam along a Z-direction of the ion beam on the wafer plane using a Z-axis component of the electrostatic lens component, wherein the changing of the height of the ion beam along the Z-direction is limited by the reduced size of the aperture. The changed height of the ion beam along the Z-direction of the ion beam on the wafer plane may correspond to a peak current of the ion beam generated in response to the adjusting performed by the Z-axis component of the electrostatic lens component.

In some implementations, the implantation system may include a focus voltage component coupled to the controller component. The method may include reducing, using the controller component, height of the ion beam on the wafer plane by reducing, using the shutter component, the size of the aperture in accordance with the minimum size of the aperture and adjusting the ion beam by changing the height of the ion beam by changing a focus voltage using the focus voltage component of the electrostatic lens component, wherein the changing of the height of the ion beam is limited by the reduced size of the aperture. The changed height of the ion beam on the wafer plane may correspond to a peak current of the ion beam generated in response to the adjusting performed by the focus voltage component of the electrostatic lens component.

In some implementations, the ion beam implantation system may include a scan offset electrostatic lens component and a post scan offset electrostatic lens coupled to the controller component. The method may include reducing, using the controller component, the height of the ion beam on the wafer plane by reducing, using the shutter component, the size of the aperture in accordance with the minimum size of the aperture and adjust the ion beam by changing the height of the ion beam on the wafer plane using at least one of: the scan offset electrostatic lens component, the post scan offset electrostatic lens, and any combination thereof, wherein the changing of the height of the ion beam is limited by the reduced size of the aperture. The height position of the ion beam on the wafer plane may correspond to a peak current of the ion beam generated in response to the adjusting performed by at least one of: the scan offset electrostatic lens component, the post scan offset electrostatic lens, and any combination thereof.

In some implementations, adjusting the ion beam may include increasing the height of the ion beam on the wafer plane. The ion beam implantation system may include a quadrupole magnet component coupled to the controller component. The method may include increasing, using the controller component, the height of the ion beam on the wafer plane by reducing, using the shutter component, the size of the aperture in accordance with the minimum size of the aperture and adjusting the ion beam by increasing the height of and reducing a width of the ion beam on the wafer plane using the quadrupole magnet component, wherein the increasing the height of and the reducing the width of the ion beam on the wafer plane is limited by the reduced size of the aperture. The increased height of the ion beam on the wafer plane may correspond to a peak current of the ion beam generated in response to the adjusting performed by the quadrupole magnet component.

The details of one or more variations of the subject matter described herein are set forth in the accompanying drawings and the description below. Other features and advantages of the subject matter described herein will be apparent from the description and drawings, and from the claims.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations. The drawings are schematic in nature and do not represent actual dimensions or aspect ratios. In the drawings,

FIG. 1 illustrates an example ion beam implantation system, according to some embodiments of the current subject matter;

FIG. 2 illustrates an example shutter component, according to some embodiments of the current subject matter;

FIGS. 3A-3B illustrate an example process for centering a beam using the ion implanter, according to some embodiments of the current subject matter;

FIGS. 4A and 4B illustrate an example beam height reduction process, according to some implementations of the current subject matter;

FIGS. 5A and 5B illustrate another example beam height reduction process, according to some implementations of the current subject matter;

FIGS. 6A and 6B illustrate an example beam height increase process, according to some implementations of the current subject matter;

FIGS. 7A and 7B illustrate an example beam height check process, according to some implementations of the current subject matter.

### DETAILED DESCRIPTION

To address these and potentially other deficiencies of currently available solutions, one or more implementations of the current subject matter relate to methods, systems, articles of manufacture, and the like that can, among other possible advantages, provide an ability to perform adjustment of beam shape in ion beam implantation systems.

The present embodiments will now be described more fully hereinafter with reference to the accompanying drawings, wherein some exemplary embodiments are shown. The subject matter of the present disclosure may be embodied in many different forms and are not to be construed as limited to the embodiments set forth herein. These embodiments are provided so this disclosure will be thorough and complete, and will fully convey the scope of the subject matter to those skilled in the art. In the drawings, like numbers refer to like elements throughout.

As used herein, an element or operation recited in the singular and proceeded with the word “a” or “an” are understood as possibly including plural elements or operations, except as otherwise indicated. Further, various embodiments herein have been described in the context of one or more elements or components. An element or component may comprise any structure arranged to perform certain operations. Although an embodiment may be described with a limited number of elements in a certain topology by way of example, the embodiment may include more or less elements in alternate topologies as desired for a given implementation. Note any reference to “one embodiment” or “an embodiment” means a particular feature, structure, or characteristic described in connection with the embodiment is included in at least one embodiment. The appearances of the phrases “in one embodiment,” “in some embodiments,” and “in various embodiments” in various places in the specification are not necessarily all referring to the same embodiment.

Ion implantation is a technique commonly employed for introducing impurities, in the form of ionized dopant particles, into a semiconductor workpiece to affect the conductivity of the workpiece in a desired manner. In some ion beam implantation systems, a “spot ion beam” (or “spot beam”) is formed of ionized particles and is scanned across a workpiece to implant the ions therein. A spot beam is an ion beam in which ions are projected as a beam having a generally circular or oval cross-sectional shape and a cross-sectional size that is significantly smaller than a surface area of a workpiece onto which the spot beam is projected. A spot beam may be projected through an electrostatic scanner adapted to controllably deflect the spot beam at varying angles in a first direction. For example, an electrostatic scanner may deflect the spot beam in a horizontal direction. The amount of deflection may be sufficient to scan the spot beam across the entire diameter of a workpiece that is being processed by the spot beam. Thus, the spot beam, which may have a width that is significantly smaller than a width of the workpiece, may be scanned horizontally across the workpiece to implant the entire width of the workpiece. Typically, a workpiece is disposed on a movable workpiece holder that is movable in a second direction perpendicular to the first direction. For example, the workpiece holder may translate the workpiece in a vertical direction. In this way, the entirety of the workpiece may be processed by the spot beam. In other words, the spot beam may be deflected back and forth in the first direction (e.g., horizontally), while the workpiece is translated in the second direction (e.g., vertically).

Ideally, when a spot beam is scanned horizontally across a workpiece, the vertical distribution of ions in the spot beam remains consistent. That is, the vertical distribution of ions in the ion beam ideally remains unchanged regardless of the horizontal position of the ion beam during scanning. However, due to non-uniformities in electrostatic scanners and other components of ion beam implantation systems, the vertical distribution of ions in a spot beam can exhibit significant variation (“dose rate variation”) as a function of the horizontal position of the spot beam. If left unaccounted for, such dose rate variation can result in a semiconductor workpiece being implanted in a highly non-uniform manner, which can detrimentally impact the performance of a resulting semiconductor device or render the semiconductor workpiece entirely useless.

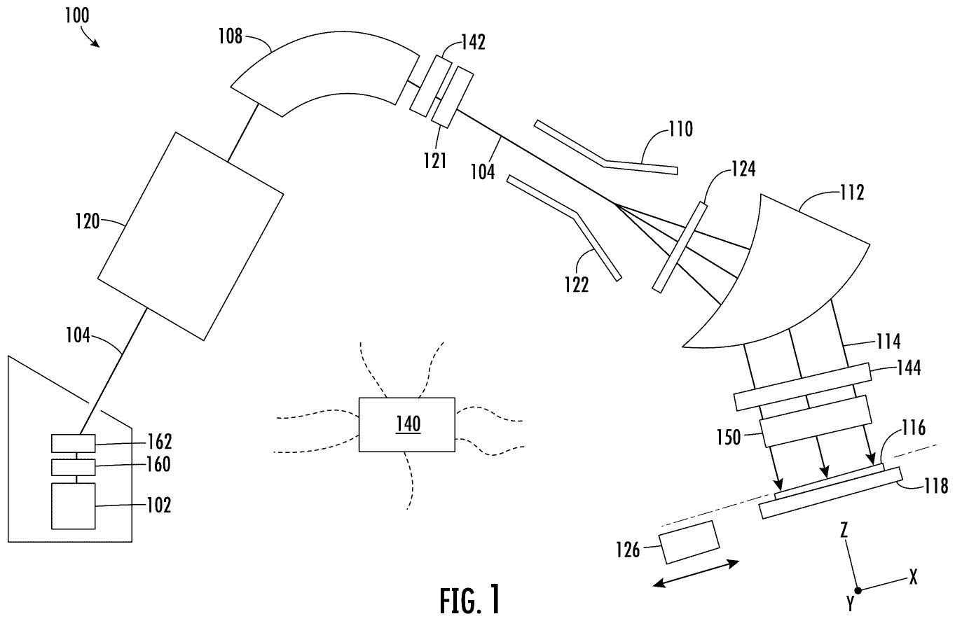

FIG. 1 illustrates an example ion beam implantation system 100 (hereinafter “the ion implanter 100”), according to some embodiments of the current subject matter. The ion implanter 100 may include an ion source 102 adapted to generate ions that are extracted from the ion source 102 in the form of a spot ion beam 104 (hereinafter, “the spot beam 104”) having a generally circular and/or oval cross-sectional shape. The ion source 102 may generate ions using any suitable technique (e.g., electron ionization, chemical ionization, plasma, electric discharge, etc.) and the spot beam 104 may be extracted from the ion source 102 using any of a variety of electrode configurations (sometimes referred to as “extraction optics”) familiar to those of skill in the art. The current subject matter is not limited in this regard.

The ion implanter 100 may further include a mass analyzer 108 located downstream from the ion source 102. The mass analyzer 108 may use magnetic fields to influence and guide the path of ions within the spot beam 104. The magnetic fields affect the flight path of ions according to their mass and charge. By proper selection of the magnetic fields, only those ions having a selected mass and charge will be directed through the mass analyzer 108. Other of the ions will be trapped by the mass analyzer 108 and will not travel any further through the ion implanter 100.

The spot beam 104 may then enter a scanner 110 located downstream from the mass analyzer 108. The scanner 110 may cause the spot beam to be fanned out into a “ribbon” formed of a plurality of divergent beamlets. The scanner 110 may be electrostatic or magnetic. A collimator 112 located downstream from the scanner 110 may then redirect the divergent beamlets into a plurality of parallel beamlets forming a scanned ion beam 114 (hereinafter, “the scanned beam 114”) that is directed toward a semiconductor workpiece 116 (hereinafter, “the workpiece 116”).

The workpiece 116 may be disposed on a movable workpiece holder 118. In some embodiments, the direction in which the scanned beam 114 travels immediately prior to striking the workpiece 116 is referred to as the Z-direction. The direction perpendicular to the Z-direction and horizontal may be referred to as the X-direction. The direction perpendicular to the Z-direction and vertical may be referred to as the Y-direction. Thus, during an implantation process, the scanner 110 may scan the spot beam 104 back and forth in the X-direction (i.e., horizontally) while the movable workpiece holder 118 is translated in the Y-direction (i.e., vertically). In some embodiments, these directions may be reversed, with the scanner 110 scanning the spot beam 104 back and forth in the Y-direction (i.e., vertically), while the movable workpiece holder 118 is translated in the X-direction (i.e., horizontally). The current subject matter is not limited in this regard.

The ion implanter 100 may also include various beam shaping components for selectively manipulating the shape of the spot beam 104 and/or the shape of the scanned beam 114. For example, the ion implanter 100 may include an early beam focusing element 120 (hereinafter, “the focus voltage 120”) located between the ion source 102 and the mass analyzer 108. The focus voltage 120 may use electrostatic voltage to focus the spot beam 104 (e.g., to adjust the height, width, and transmission characteristics of the spot beam 104). In some embodiments, the focus voltage 120 may be configured to perform adjustment of the beam along the Y-direction by ramping up or increasing voltage from low voltage to high voltage, so that a new focusing of the beam may be determined during beam adjustment process (as discussed herein).

In some embodiments, the ion implanter 100 may include a Z-axis of an extraction suppression electrode component 162 (“Z-component”). The Z-component 162 may be positioned between the ion source 102 and the focus voltage 120. The Z-component 162 may be configured to perform in-out (e.g., along the Z-axis) focusing of the beam generated by the ion source 102. The ion implanter 100 may also include a Y-axis of the extraction suppression electrode component 160 (“Y-component”). The Y-component 160 may likewise be positioned between the ion source 102 and the focus voltage 120. In some example, non-limiting embodiments, the Y-component 160 may be positioned between Z-component 162 and the focus voltage 120. Alternatively, the Z-component 162 may be positioned between Y-component 160 and the focus voltage 120. The Y-component 160 may be configured to perform up-down (e.g., along the Y-axis) steering of the beam generated by the ion source 102. The components 160 and 162 may be configured to perform their respective adjustments separately from one another (in any desired sequence) and/or simultaneously.

The beam shaping components of the ion implanter 100 may further include a quadrupole (“quad”) magnet and/or any other type of magnet 121 located downstream from the mass analyzer 108. The magnet 121 may employ a magnetic or electrical field to focus, defocus, and/or steer the spot beam 104. The magnet 121 may, for example, be set to a quad mode or a dipole mode, where the quad mode may be used to control the spot beam 104 height and shape, while the dipole mode may be used to steer the spot beam vertically. The current subject matter is not limited in this regard. Alternatively, or in addition, a dipole magnet 142 may be positioned in the path of the beam (as shown in FIG. 1) so, upon activation of the dipole magnet 142, the beam may be moved along the Y-direction to ensure that the beam is centered on the workpiece 116 located on the movable workpiece holder 118 in the end station. In some embodiments, the quad magnet 121 and the dipole magnet 142 may be separate components of the ion implant 100 and/or be combined into a single component and/or be a single component that may perform functions of the quad magnet 121 and/or the dipole magnet 142.

The beam shaping components of the ion implanter 100 may further include a scanner offset control 122 that may be integral with the scanner 110. The scanner offset control 122 may facilitate increasing/decreasing the size of the spot beam 104.

The beam shaping components of the ion implanter 100 may further include a post scan suppression element 124 located downstream from the scanner 110. The post scan suppression element 124 may include an electrostatic lens capable of increasing/decreasing the size of the scanned beam 114.

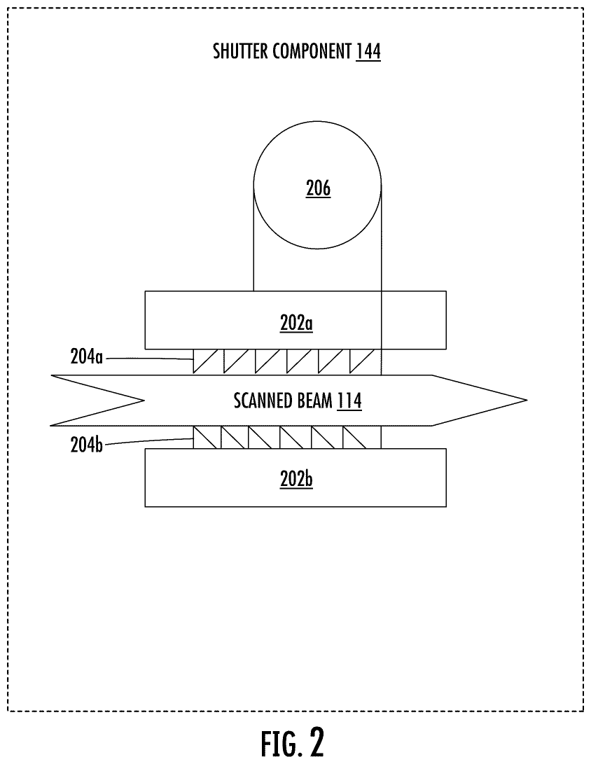

In some embodiments, the beam shaping or adjustment components of the ion implanter 100 may also include a shutter component 144. The shutter component 144 may be positioned subsequent to the collimator 112 and prior to a profile Faraday component 150. Alternatively, or in addition, the collimator magnet 112 may be absent from the setup in the ion implanter 100. The shutter component 114 may be configured to operate on an electrostatically scanned beam that does not include an upstream collimator magnet 112. The shutter component 144 (as further shown in FIG. 2) may be configured to mechanically adjust and/or limit aperture (e.g., by adjusting along a vertical dimension) through which a beam may pass onto the workpiece 116. The size of the aperture provided by the shutter component 144 may be defined by the beam recipe that may be provided to the ion implanter 100. The shutter component 144 may be configured to facilitate centering and/or re-centering of the beam using any of the positional components, increasing and/or decreasing height of the beam, focusing the beam, and/or performing any other beam manipulations, and/or any combinations thereof.

The profile Faraday component 150 may be a controllable component that may be movable across the scanned beam 114 (e.g., driven by a servo motor or the like), such as, for example, back and forth in the X-direction. In some embodiments, the profile Faraday component 150 may include one or more current sensing devices (e.g., Faraday devices or cups, and/or any other type of sensing devices) that may be arranged in any desired way (e.g., vertically extending columns (i.e., extending in the Y-direction, perpendicular to the direction of movement of the profile Faraday component 150)). The current sensing devices of the profile Faraday component 150 may be configured to pass across a vertical center (and/or near the vertical center) of the scanned beam 114 when the profile Faraday component 150 is moved horizontally across the scanned beam 114.

The above-described beam shaping components of the ion implanter 100 are provided by way of example only. The ion implanter 100 may include various additional or alternative components or elements for controllably adjusting the shape, size, and other attributes of the spot beam 104 and/or the scanned beam 114. Such components and their effects on the spot beam 104 and/or the scanned beam 114 will be familiar to those of skill in the art and their inclusion/exclusion will depend on the particular ion implanter used and its intended applications.

The ion implanter 100 may also include a movable beam profiler 126, which may be located adjacent the movable workpiece holder 118. The movable beam profiler 126 may be adapted to measure beam current across the scanned beam 114 to develop a beam profile thereof as further described below. During a beam profiling process, the movable workpiece holder 118 may be moved out of the path of the scanned beam 114 (out of a nominal, “implantation position”), and the movable beam profiler 126 may be translated across the scanned beam 114 in the X-direction, along substantially the same plane previously occupied by the front surface of the movable workpiece holder 118. Alternatively, the movable workpiece holder 118 may be left in its implantation position and the movable beam profiler 126 may be translated across the scanned beam 114 in front of the movable workpiece holder 118. Thus, the movable beam profiler 126 may measure the beam current of the scanned beam 114 at substantially the same locations where the scanned beam 114 would normally impinge on a semiconductor workpiece (e.g., the workpiece 116) during an ion implantation process.

The ion implanter 100 may include a main controller 140 operatively coupled to the various components of the ion implanter 100 described herein, including the beam shaping components and the movable beam profiler 126, for controlling and/or coordinating operation of such components. The main controller 140 may include one or more processors, such as, a microprocessor, dedicated semiconductor processor chip, general purpose semiconductor processor chip, and/or similar device, and/or any combination of processing devices. The main controller 140 may include a memory and/or a memory unit coupled to the processor(s), where the memory unit may include software for executing various processes described herein.

The memory unit of the main controller 140 may include an article of manufacture. In some embodiments, the memory unit may include any non-transitory computer readable medium and/or machine readable medium, such as, an optical, magnetic and/or semiconductor storage. The storage medium may store various types of computer executable instructions to implement one or more of logic flows described herein. Examples of a computer readable or machine-readable storage medium may include, but are not limited to, any tangible media capable of storing electronic data, including volatile memory or non-volatile memory, removable or non-removable memory, erasable or non-erasable memory, writeable or re-writeable memory, etc. Examples of computer executable instructions may include any suitable type of code, such as source code, compiled code, interpreted code, executable code, static code, dynamic code, object-oriented code, visual code, and the like. The current subject matter is not limited in this context.

Any or all of the above-described beam shaping components of the ion implanter 100 may be manipulated and/or adjusted by changing one or more settings of such components via the main controller 140. These settings, which may serve as tunable parameters as described herein, include, but are not limited to, positioning of mechanical aperture elements, focus voltage, magnet current, amount of force applied to a force-driven optical element, electrostatic optical element current, post scan suppression, scanner offset, source life, cell suppression, scanned beam velocity, etc. The current subject matter is not limited in this regard. Thus, the various beam shaping components of the ion implanter 100 may be associated with one or more tunable parameters that can be changed to affect the shape and/or other attributes of the spot beam 104 and/or the scanned beam 114.

FIG. 2 illustrates an example shutter component 144, according to some embodiments of the current subject matter. The shutter component 144 may include a first aperture limiting portion 202a having one or more aperture limiting teeth 204a, a second aperture limiting portion 202b having one or more aperture limiting teeth 204b, and a rotational pulley component 206. The rotational pulley component 206 may be coupled to the first aperture limiting portion 202a and second aperture limiting portion 202b. The rotational pulley component 206, and thus, the first and second aperture limiting portions 202a and 202b, may be controlled by the main controller 140 (not shown in FIG. 2), and may serve as limiting apertures that may be used to alter shape and/or position of the scanned beam 114 on the workpiece 116, as discussed herein (not shown in FIG. 2).

Upon receiving one or more signals from the main controller 140, the rotational pulley component 206 may be configured to rotate, and, thereby, cause movement of the first aperture limiting portion 202a and second aperture limiting portion 202b. The main controller 140 may generate such signals based on the beam recipe that may have been provided to it. For example, clockwise rotation of the rotational pulley component 206 may be configured to move the aperture limiting portions 202a and 202b closer together. Movement of the portions 202a and 202b closer together causes their respective aperture limiting teeth 204a and 204b to begin interacting with and/or scraping the scanned beam 114, which in turn, causes change in the scanned beam current that may be detected and/or measured in the end station containing the workpiece 116. For example, lower scanned beam current may be detected/measured when aperture limiting portions 202a and 202b are closer together and the teeth 204a and 204b scrape the scanned beam 114. In contrast, counterclockwise rotation of the rotational pulley component 206 may be configured to move the aperture limiting portions 202a and 202b further apart. Movement of the portions 202a and 202b apart together causes one or more of their respective aperture limiting teeth 204a and 204b to stop interacting with and/or scraping the scanned beam 114, which in turn, may cause higher scanned beam current being detected and/or measured in the end station containing the workpiece 116. As can be understood, direction of rotation of the rotational pulley component 206 may be entirely arbitrary (i.e., the current subject matter is not limited to specific direction described herein, e.g., counterclockwise rotation may cause portions 202a and 202b to move closer together and clockwise rotation may cause portions 202a and 202b to move further apart). Moreover, the movement of the aperture limiting portions 202a and 202b may effectuated using any other desired mechanism, e.g., hydraulic cylinders, magnetic actuators, etc. The current subject matter is not limited these embodiments.

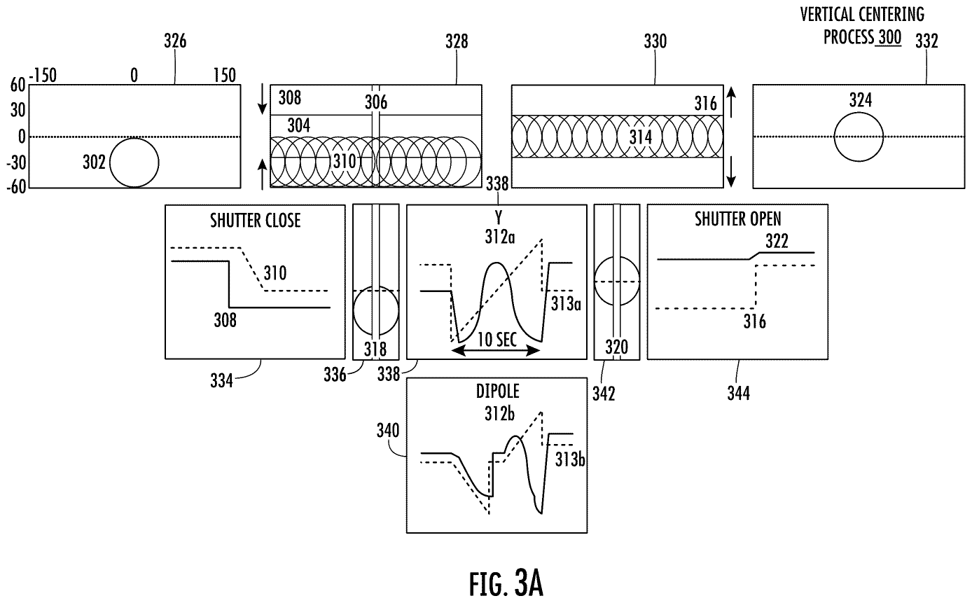

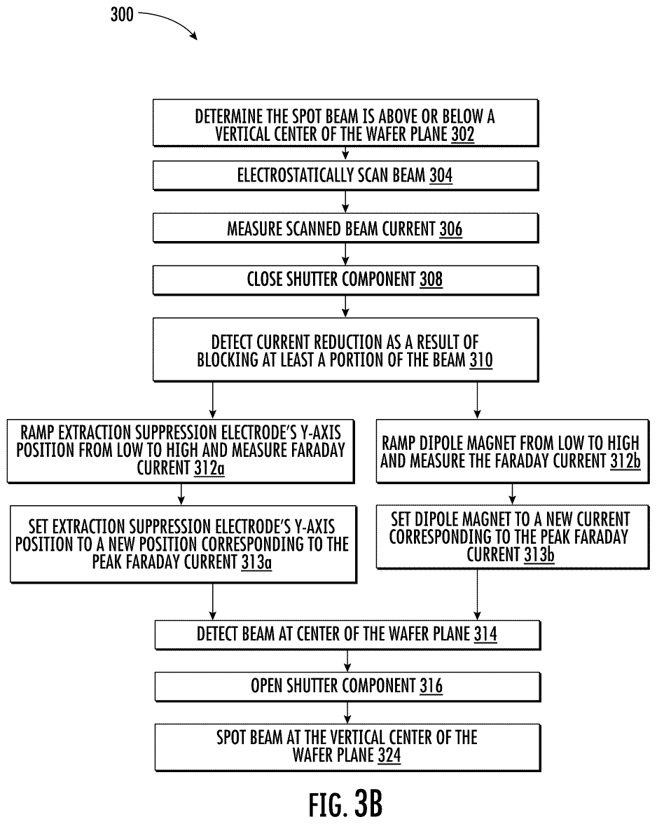

FIGS. 3A-3B illustrate an example process 300 for centering a beam using the ion implanter 100, according to some embodiments of the current subject matter. FIG. 3A is a schematic of the vertical centering process 300 and FIG. 3B is a corresponding flowchart. The process 300 may be performed with the aid of the shutter component 144 as well as at least one of the Y-component 160, which may be configured to adjust the beam along the Y-direction by performing up-down (“ramping up”) movement of the extraction suppression electrode/electrostatic lens that is positioned proximate to the ion source 102, and/or the dipole magnet 142. The main controller 140 may be configured to control operation of each of the shutter component 144, the Y-component 160, and/or the dipole magnet 142. The operations may include opening and/or closing of the first aperture limiting portion 202a and second aperture limiting portion 202b of the shutter component 144.

At 302 (as shown in FIG. 3B), the main controller 140 may determine that the spot beam 104 is below a vertical center of the wafer plane (as shown by frame 326 in FIG. 3A). For instance, the main controller 140 may determine that the center of the spot beam 104 may be located about 30 mm below the vertical center of the wafer plane. At 304, the scanner 110 may be configured to perform electrostatic scanning of the beam using a constant linear profile speed, thereby forming scanned beam 114. At 306, the profile Faraday component 150 may be moved to the center of the wafer plane, at 318, and scanned beam 114 current may be measured, as shown by the frames 328 and 336 in FIG. 3A.

At 308, the main controller 140 may trigger closing of the shutter component 144. In some embodiments, one or more of the aperture limiting portions 202a and 202b may be moved closer to one another and/or within a predetermined distance of one another (as shown by frame 328 in FIG. 3A). For instance, the aperture limiting portions 202a and 202b may be moved within 25 mm of each other, as may defined by the recipe received by the main controller 140. As can be understood, any desired aperture may be created by the portions 202a and 202b.

Further, at 308, now that the aperture limiting portions 202a and 202b are blocking at least a portion of the scanned beam 114, the profile Faraday component 150 may be configured to detect a reduction or a drop in the current of the scanned beam 114, at 310. This is shown by the frame 334 in FIG. 3A.

Once drop in scanned beam 114 current is detected, the main controller 140 may be configured to use Y-component 160 and/or dipole magnet 142 to adjust vertical position (i.e., Y-position) of the beam with respect to the wafer plane. As can be understood, one or both may be used for this purpose, where Y-component 160 may be used to initially adjust the vertical position of the beam and dipole magnet 142 may be used to fine-tune the initial adjustment and/or vice versa. If the Y-component 160 is used, at 312a, the Y-component 160 may be configured to perform adjustment of the spot beam 104 along the Y-direction by having the main controller 140 trigger movement (ramping up) of the Y-component to adjust position of the electrostatic lens/extraction suppression electrode from low (down) to high (up), as measured in millimeters (mm), and measure the Faraday current, as shown by frame 338 in FIG. 3A, so that a new position (e.g., new peak current) of the beam may be determined during beam adjustment process (e.g., as shown by the frame 330 in FIG. 3A). The position ramping (i.e., low to high) may be performed during a predetermined period of time (e.g., 10 seconds and/or any other time period). The Y-axis position of the extraction suppression electrode may then be set to a new position, at 313a, which may correspond to the peak Faraday current. Alternatively, or in addition, at 312b, the dipole magnet 142 may be activated (e.g., by ramping current of the dipole magnet from low to high and measuring Faraday current) to cause the scanned beam 114 to be moved along the Y-direction to ensure that the scanned beam 114 is centered on the wafer plane (as shown by frame 340 in FIG. 3A). The dipole magnet may be set, at 313b, to a new current corresponding to the peak Faraday current. The main controller 140 may determine that the scanned beam 114 is located between the portions 202a and 202b, i.e., vertically centered on the wafer plane, by using the profile Faraday component 150 (at 320 shown in frame 342 in FIG. 3A) to measure the current of the scanned beam 114 (as shown by the rounded peak in frame 338 in FIG. 3A).

Upon the scanned beam 114 being centered on the wafer plane, at 314 (as shown in the frame 330 in FIG. 3A), the main controller 140 may trigger opening of the shutter component 144 (i.e., pulling portions 202a and 202b apart), at 316. Once the shutter component 144 is opened, the scanned beam 114 current may temporarily increase (at 322 as shown in frame 344 in FIG. 3A) if the recipe's shutter aperture was less than the beam height before it was opened. With the shutter component 144 out of the way, the stationary spot beam (at 324, as shown in FIGS. 3A-B) is now vertically centered on the wafer plane, as shown in frame 332 in FIG. 3A. In some embodiments, one of the benefits of the process 300 is that it may perform vertical adjustment of the beam in a short period of time (e.g., 10 seconds) as compared to conventional systems that may take up to a minute to perform beam adjustments.

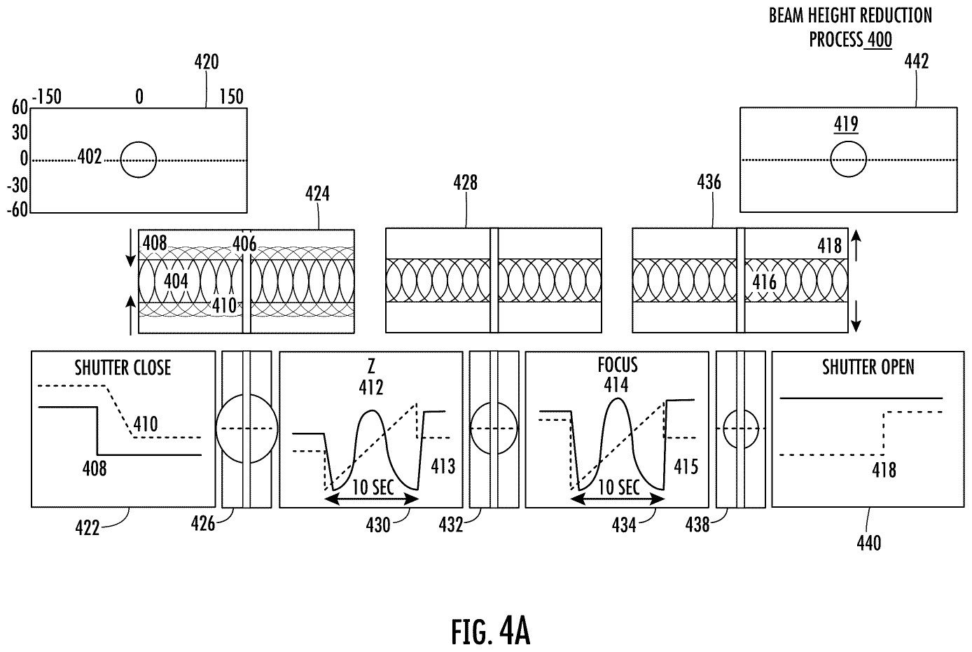

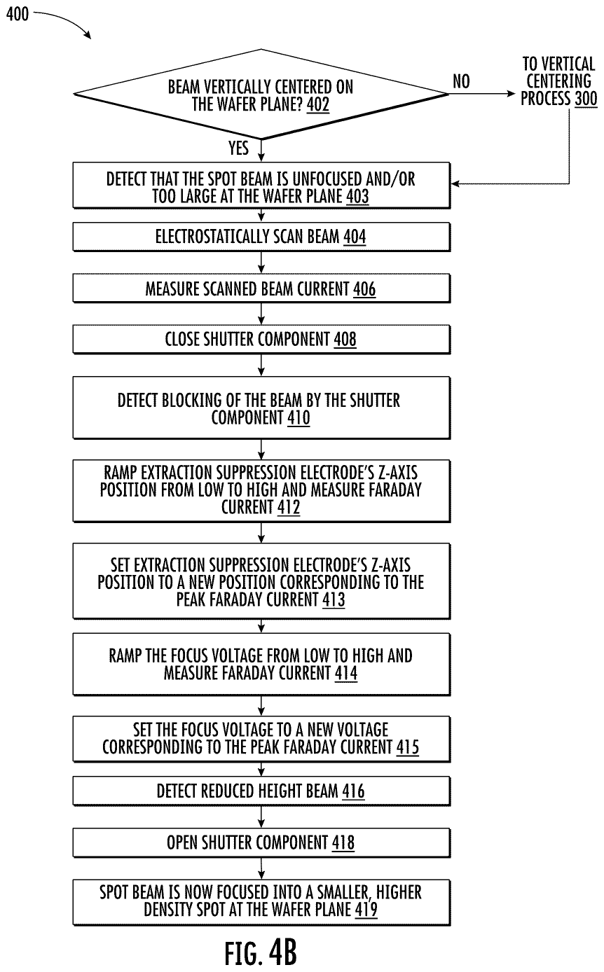

FIGS. 4A and 4B illustrate an example beam height reduction process 400, according to some implementations of the current subject matter. The process 400 may be performed by the ion implanter 100, and in particular, may be controlled using main controller 140. FIG. 4A is a schematic of the beam height reduction process 400 and FIG. 4B is a corresponding flowchart. The process 400 may be performed with the aid of the shutter component 144 as well as at least one of the Z-component 162 (which may adjust the beam along the Z-direction by performing in-out (“ramping up”) movement of the extraction suppression electrode/electrostatic lens towards and/or away from the ion source 102). The main controller 140 may be configured to control operation of each of the shutter component 144 and/or the focus voltage 120. The operations may include opening and/or closing of the first aperture limiting portion 202a and second aperture limiting portion 202b of the shutter component 144.

As shown in FIG. 4B, the process 400 may be configured to determine that the beam height (as shown by frame 420 and frame 426 in FIG. 4A) may need to be reduced (e.g., it may be greater than the beam height defined by the recipe received by the main controller 140) to the height shown in the frame 442, as shown in FIG. 4A. To initiate the process 400, at 402, the main controller 140 may determine whether the spot beam 104 is vertically centered on the wafer plane. If not, the main controller 140 may be configured to perform vertical centering process 300 to ensure that the spot beam 104 is vertically centered with regard to the wafer plane. Otherwise, the processing may proceed to 403, where a determination may be made that the spot beam is unfocused and/or too large at the wafer plane.

At 404, the scanner 110 may be configured to perform electrostatic scanning of the beam using a constant linear profile speed, thereby forming scanned beam 114. At 406, the profile Faraday component 150 may be moved to the center of the wafer plane and scanned beam 114 current may be measured, as shown by the frame 424.

At 408, the main controller 140 may trigger closing of the shutter component 144. The aperture limiting portion(s) 202a and 202b of the shutter component 144 may be moved closer to one another and/or within a predetermined distance of one another (as shown by frame 424 in FIG. 4A). For instance, the aperture limiting portion(s) 202a and 202b may be moved within 25 mm of each other, as may defined by the recipe received by the main controller 140, which may include the height of the beam that is desired. As can be understood, any aperture may be created by the portions 202a and 202b.

At 410, once that the aperture limiting portion(s) 202a and 202b are blocking at least a portion of the scanned beam 114, the profile Faraday component 150 may be configured to detect a reduction or a drop in the current 410 of the scanned beam 114. This is shown by the frame 422 in FIG. 4A.

Upon detecting a drop in the scanned beam 114 current, the main controller 140 may be configured to use one or more aspects of the Z-component 162 to adjust the focal point of the beam along the Z-direction and/or further focus the beam with respect to the wafer plane. In particular, in some embodiments, a high-voltage electrode and/or electrostatic lens manipulator component may be configured to perform adjustment of the spot beam 104 along the Z-direction, by having the main controller 140 trigger movement (ramping up) of the Z-component 162 to adjust position of the electrostatic lens/extraction suppression electrode from in (toward the ion source 102) to out (away from the ion source 102), as measured in millimeters (mm), and measure the Faraday current, as shown by frame 430 in FIG. 4A, so that a new height (e.g., corresponding to new peak current) of the beam may be determined (e.g., as shown by the frame 428 and frame 432 in FIG. 4A), at 412. The extraction suppression electrode's z-axis position may be set to a new position corresponding to the peak Faraday current, at 413. Alternatively, or in addition, if further reduction in beam's height is desired, at 414, the focus voltage 120 of the electrostatic lens may be used. The main controller 140 may be configured to ramp up voltage supplied to the focus voltage 120 from low voltage to high voltage, as shown by frame 434 in FIG. 4A. Moreover, the focus voltage may be set to a new focus voltage corresponding to the peak Faraday current, at 415. By focusing the beam even further, the main controller 140 may be configured to determine a new voltage at a new peak current of the beam associated with a new beam height (as shown in by the frame 438 in FIG. 4A), at 416. In some embodiments, the voltage increase(s), at 412 and/or 414, may be performed during a predetermined period of time (e.g., 10 seconds and/or any other time period).

Upon the scanned beam 114 being focused in accordance with the recipe (as shown in the frame 438 in FIG. 4A), the main controller 140 may trigger opening of the shutter component 144 (i.e., pulling portions 202a and 202b apart), at 418 (as shown by frame 436 in FIG. 4A). Frames 440 and 442 in FIG. 4A illustrate appearance of the beam on the wafer plane with the portions 202a and 202b out of the way. The spot beam is now focused into a smaller, higher density spot at the wafer plane, at 419 (as shown by frame 442 in FIG. 4A). In some embodiments, one of the benefits of the beam height reduction process 400 is that it may perform reduction in beam height in a short period of time (e.g., 10 seconds) as compared to conventional systems that may take up to more than a minute to perform such beam adjustment.

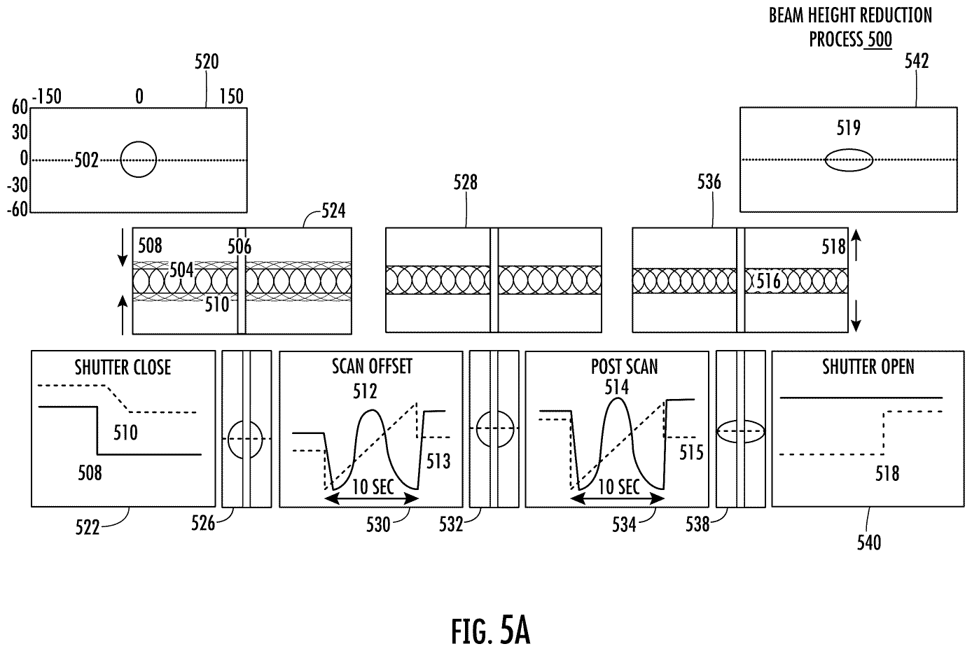

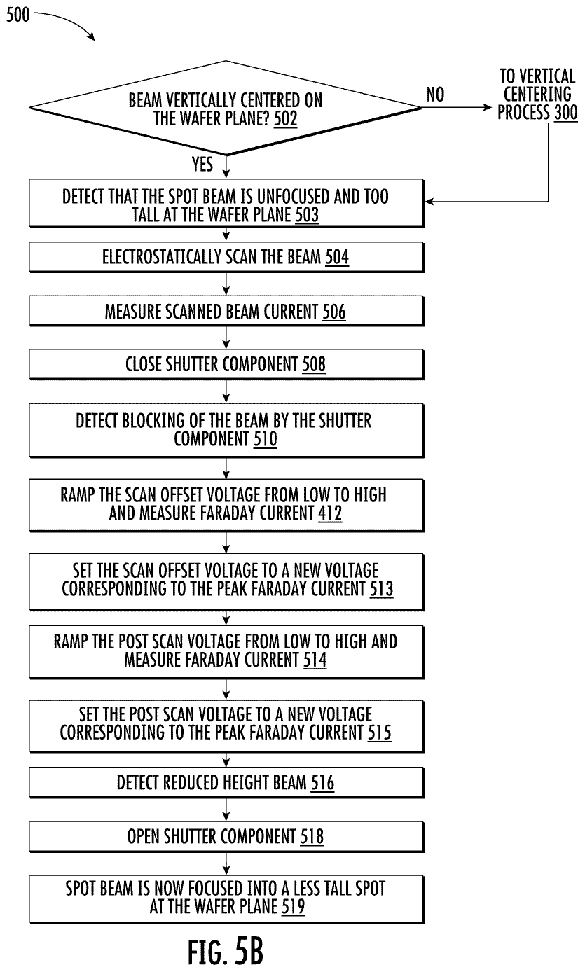

FIGS. 5A and 5B illustrate another example beam height reduction process 500, according to some implementations of the current subject matter. The process 500 may also be performed by the ion implanter 100, and in particular, may be controlled using main controller 140. FIG. 5A is a schematic of the beam height reduction process 500 and FIG. 5B is a corresponding flowchart. The process 500 may be performed with the aid of the shutter component 144 as well as at least one of the scanner offset control 122 (which may adjust the height of the beam along one or more directions by ramping up or increasing voltage) and a post scan suppression element 124 (which may further fine tune the height of the beam along one or more directions by ramping up or increasing voltage). The main controller 140 may be configured to control operation of each of the shutter component 144 and/or the scanner offset control 122 and/or post scan suppression element 124. The operations may include opening and/or closing of the first aperture limiting portion 202a and second aperture limiting portion 202b of the shutter component 144.

Referring to FIG. 5B, the beam height reduction process 500 may be configured to determine that the beam height (as shown by frame 520 and frame 526 in FIG. 5A) may need to be reduced (e.g., it may be greater than the beam height defined by the recipe received by the main controller 140) to the height shown in the frame 542, as shown in FIG. 5A. At 502, the main controller 140 may determine whether the spot beam 104 is vertically centered on the wafer plane. If not, the main controller 140 may be configured to perform vertical centering process 300 to ensure that the spot beam 104 is vertically centered with regard to the wafer plane. Otherwise, the processing may proceed to 503, where a determination may be made that the spot beam is unfocused and/or too tall at the wafer plane.

Similar to the processes 300 and 400, at 504, the scanner 110 may be configured to perform electrostatic scanning of the beam using a constant linear profile speed, thereby forming scanned beam 114. At 506, the profile Faraday component 150 may be moved to the center of the wafer plane and scanned beam 114 current may be measured, as shown by the frame 524.

At 508, the main controller 140 may trigger closing of the shutter component 144. The aperture limiting portion(s) 202a and 202b of the shutter component 144 may be moved closer to one another and/or within a predetermined distance of one another (as shown by frame 524 in FIG. 5A). For instance, the aperture limiting portion(s) 202a and 202b may be moved within 15 mm of each other, as may defined by the recipe received by the main controller 140, which may include the height of the beam that is desired. As can be understood, any aperture may be created by the portions 202a and 202b.

At 510, once that the aperture limiting portion(s) 202a and 202b are blocking at least a portion of the scanned beam 114, the profile Faraday component 150 may be configured to detect a reduction or a drop in the current 510 of the scanned beam 114. This is shown by the frame 522 in FIG. 5A.

At 512, the main controller 140 may be configured to use the electrostatic lens of the scanner offset control 122 to adjust the height of the beam. The scan offset voltage may be set to a new voltage corresponding to the peak Faraday current, at 513. In particular, in some embodiments, the main controller 140 may be configured to increase voltage supplied to the electrostatic lens of the scanner offset control 122 from a low voltage to a high voltage, as shown by frame 530 in FIG. 5A, so that a new height (e.g., corresponding to new peak current) of the beam may be determined (e.g., as shown by the frame 528 and frame 532 in FIG. 5A). The scanned beam 114 and/or the spot beam 104 may now be more focused while having a reduced height. In some embodiments, the width of the beam (as shown in the frame 532 in FIG. 5A), may increase while its height is being decreased.

At 514, the main controller 140 may trigger the post scan suppression element 124 to perform further adjustment of the height of the beam. The post scan voltage may be set to a new voltage corresponding to the peak Faraday current, at 515. Here, the main controller 140 may trigger increase in voltage supplied to the electrostatic lens of the post scan suppression element 124 from a low voltage to a high voltage, as shown by frame 534 in FIG. 5A. As a result, the scanned beam 114 and/or the spot beam 104 are now even more focused while having even further reduced height. By focusing the beam even further, the main controller 140 may be configured to determine a new voltage at a new peak current of the beam associated with a new beam height (as shown in by the frame 538 in FIG. 5A). In some embodiments, the voltage increases, at 512 and/or 514, may be performed during predetermined period(s) of time (e.g., 10 seconds and/or any other desired period of time).

Upon the scanned beam 114 being focused in accordance with the recipe, (as shown, at 516, in the frame 538 in FIG. 5A), the main controller 140 may trigger opening of the shutter component 144 (i.e., pulling portions 202a and 202b apart), at 518 (as shown by frame 536 in FIG. 5A). The spot beam is now focused into a less tall spot at the wafer plane, at 519. Frames frame 540 and frame 542 in FIG. 5A illustrate appearance of the beam on the wafer plane with the portions 202a and 202b out of the way. In some embodiments, one of the benefits of the beam height reduction process 500 is that it may perform reduction in beam height in a short period of time (e.g., 10 seconds) as compared to conventional systems that may take up to more than a minute to perform such beam adjustment.

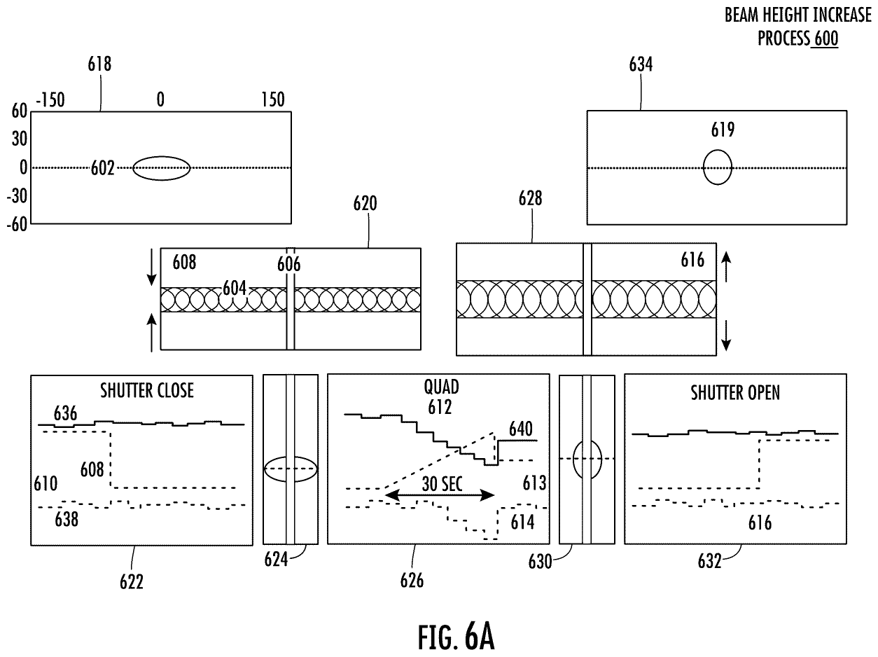

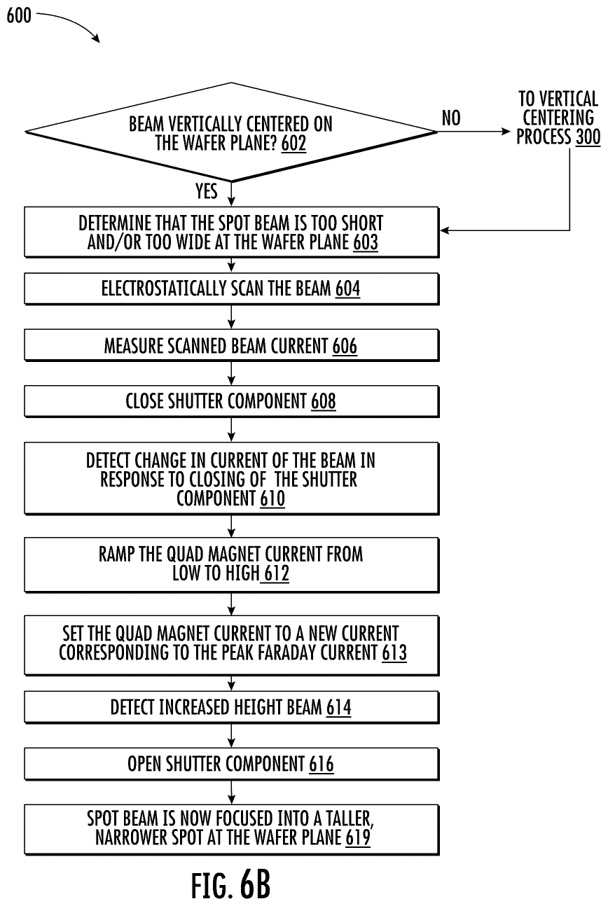

FIGS. 6A and 6B illustrate an example beam height increase process 600, according to some implementations of the current subject matter. The process 600 may likewise be executed by the ion implanter 100. Various aspects of it may be controlled by the main controller 140. FIG. 6A is a schematic of the beam height increase process 600 and FIG. 6B is a corresponding flowchart. The beam height increase process 600 may be performed using the shutter component 144 and the optical elements 121, in particular, its quadrupole magnet (hereinafter, “quad magnet”) that may be used to control the height and/or shape of the beam. The main controller 140 may be configured to control operation of each of the shutter component 144 and/or the optical elements 121. As with the discussions above, the operations of the shutter component 144 may include opening and/or closing of the first and second aperture limiting portions 202a and 202b.

Referring to FIG. 6B, the main controller 140 may be configured to determine that the beam height (as shown by frame 618 in FIG. 6A) may need to be increased (e.g., it may be less than the beam height defined by the recipe received by the main controller 140) to the height shown in the frame 634, as shown in FIG. 6A. At 602, the main controller 140 may determine whether the spot beam 104 is vertically centered on the wafer plane. If the spot beam is not vertically centered on the wafer plane, the main controller 140 may return to perform the vertical centering process 300 shown in FIGS. 3A and 3B. This, as discussed above, may ensure that the spot beam 104 is vertically centered with regard to the wafer plane. Otherwise (and/or once the beam is vertically centered), the main controller 140 may proceed to 603, where a determination may be made that the spot beam is too short and/or too wide at the wafer plane.

Similar to the processes 300 and 400 and 500, at 604, the scanner 110 may be configured to perform electrostatic scanning of the beam using a constant linear profile speed, thereby forming scanned beam 114. At 606, the profile Faraday component 150 may be moved to the center of the wafer plane and scanned beam 114 current may be measured, as shown by the frame 620.

At 608, the main controller 140 may trigger closing of the shutter component 144 (as shown by frame 622). The aperture limiting portion(s) 202a and 202b of the shutter component 144 may be moved closer to one another and/or within a predetermined distance of one another (as shown by frame 624 in FIG. 6A). By way of a non-limiting example, the aperture limiting portion(s) 202a and 202b may be moved within 20 mm of each other, as may defined by the recipe received by the main controller 140, which may include the height of the beam that is desired. As can be understood, any aperture may be created by the portions 202a and 202b. At 610, the main controller 140 may detect a change in the current of the beam in response to the closing of the portions 202a and 202b of the shutter component 144.

At 612, the main controller 140 may be configured to activate the optical elements 121 to perform adjustment of the height of the beam (e.g., by increasing it) and the width of the beam (e.g., by reducing it). To do so, the main controller 140 may be configured to ramp up magnet current from low to high as supplied to the quad magnet 121. At 613, the quad magnet current may be set to a new current corresponding to the peak Faraday current. The current ramp up may be performed during a predetermined period of time (e.g., 30 seconds and/or any other desired period of time). The current and/or width of the beam may be monitored every predetermined period of time (e.g., every 2 seconds) (e.g., shown at spot beam width curve 636 and beam current curve 638). The desired beam height may be achieved when the beam current starts to drop from being clipped by the portion(s) 202a and/or 202b (as shown by 614 in frame 626 in FIG. 6A). In some embodiments, a desired beam width may also be monitored and/or adjusted by the main controller 140. In this case, the beam width signal may continuously decrease as the beam height increases (as shown by 640 in frame 626 in FIG. 6A). The beam width 612 may be continuously determined at the same time as the beam current 614. Frame 626 shows the width and current decrease as the beam becomes more narrow and taller and starts to be clipped by the portions 202a and 202b during the quad magnet current ramping. Frame 630 in FIG. 6A illustrates beam shape subsequent to the adjustment, which the main controller 140 may detect, at 614.

At 616, the main controller 140 may trigger opening of the shutter component 144 (i.e., pulling portions 202a and 202b apart) (as shown by frame 528 in FIG. 6A). At 619, the spot beam is now focused into a taller, narrower spot beam at the wafer plane. Frames 632 and 634 in FIG. 6A illustrate appearance of the beam on the wafer plane with the portions 202a and 202b out of the way. The beam current is the same as the current before the beam height and/or width was adjusted. In some embodiments, one of the benefits of the beam height increase process 600 is that it may perform adjustments to height and/or width of the beam in a short period of time (e.g., 30 seconds) as compared to conventional systems that may take up to more than a minute to perform such beam adjustment.

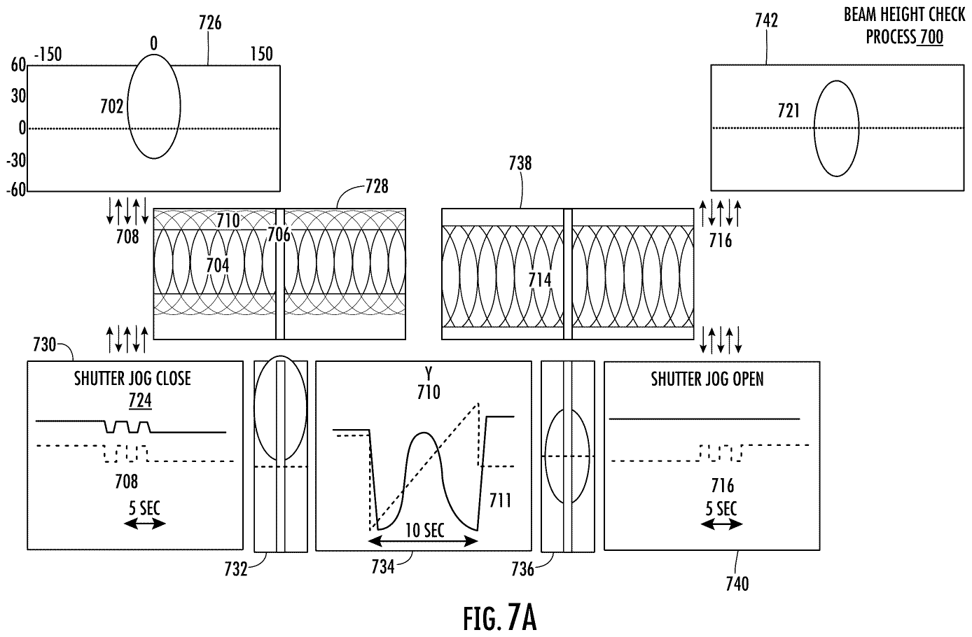

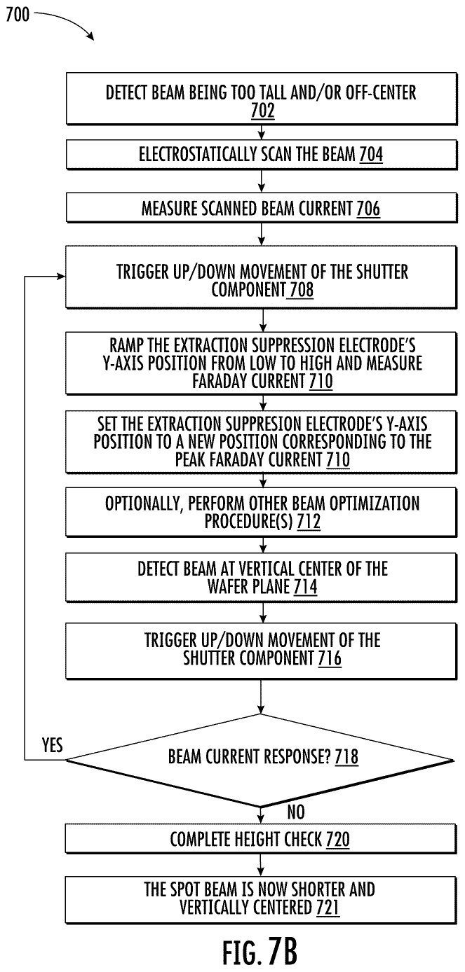

FIGS. 7A and 7B illustrate an example beam height check process 700, according to some implementations of the current subject matter. The process 700 may likewise be executed by the ion implanter 100, where some and/or all aspects of it may be controlled by the main controller 140. FIG. 7A is a schematic of the beam height check process 700 and FIG. 7B is a corresponding flowchart. The beam height check process 700 may be performed with the aid of the shutter component 144 and the electrostatic lens component, one and/or both of which that may be used to control the height and/or shape of the beam. The main controller 140 may be configured to control operation of each of the shutter component 144 and/or the electrostatic lens. As with the discussions above, the operations of the shutter component 144 may include opening and/or closing of the first and second aperture limiting portions 202a and 202b.

Referring to FIG. 7B, at 702, the main controller 140 may be configured to determine that the spot beam 104 may be vertically off-center and/or may be “too tall” (e.g., as shown by frames 726 and 732 in FIG. 7A). At 704, the main controller 140 may trigger the scanner 110 to perform electrostatic scanning of the beam using a constant linear profile speed (as shown by the frame 728 in FIG. 7A). The main controller 140 may then move profile Faraday component 150 to the center of the wafer plane and measure the scanned spot beam current, at 706.

At 708, the main controller 140 may be configured to trigger up and down movement of the aperture limiting portions 202a and 202b. The portions 202a and 202b may be moved within predetermined distance of one another (e.g., 50 mm), which may be defined by a recipe received by the main controller 140. The main controller 140 may be configured to trigger such up and down movement of the shutter component 144's portions 202a and 202b one or more times. Because a portion of the beam (e.g., a top portion of the beam as shown by frames 728 and 730) is being blocked by one of the portions 202a and 202b (e.g., 202a, as shown in FIG. 7A) during such up and down movement, the beam current may oscillate as a result (as shown by 724 in frame 730 of FIG. 7A). In some embodiments, the main controller 140 may determine the magnitude of the beam current oscillation to determine whether vertical centering process 300 shown in FIGS. 3A-B may need to be performed to focus the beam at the vertical center. Otherwise, the processing may proceed to 710. In some embodiments, the up and down movement of the shutter component 144 may be performed during a predetermined period of time (e.g., 5 seconds and/or any other period of time).

At 710 (as shown in FIG. 7A), the main controller 140 may be configured to trigger the Y-component 160, and in particular, its electrostatic lens manipulator component to perform adjustment of the spot beam 104 along the Y-direction by having the main controller 140 trigger movement (ramping up) of the Y-component to adjust position of the electrostatic lens/extraction suppression electrode from low (down) to high (up), as measured in millimeters (mm), and measure the Faraday current, as shown by frame 734 in FIG. 7A, so that a new position, corresponding to new peak current, of the beam may be determined. At 711, the extraction suppression electrode's Y-axis position may be set to a new position corresponding to the peak Faraday current. The position ramping may be performed during a predetermined period of time (e.g., 10 seconds and/or any other time period). At 712, optionally, any other beam optimization processes (e.g., similar to those shown and discussed in connection with FIGS. 4A-6B) may be executed by the main controller 140.

At 714, the main controller 140 may determine/detect that the scanned beam and/or the spot beam is now at the vertical center with respect to the wafer plane and/or less “tall” (e.g.,

### SUBSTITUTE SPECIFICATION-CLEAN VERSION

lesser height than that the height of the beam as determined at 702). This is shown by frames 736 and 738.

At this stage, the main controller 140 may be configured to repeat the height check of the beam by triggering up and down movement of shutter component 144's portions 202a and/or 202b, at 716 (as shown by frame 740 in FIG. 7A). The up and down movements may be performed during a predetermined period of time (e.g., 5 seconds). If, at 718, there is no change in beam current, the beam height check process 700 may be terminated, at 720. The spot beam is now shorter and vertically centered, at 721 (as shown by frame 742 in FIG. 7A). Otherwise, the main controller 140 may be configured to return to 708 and perform the beam height check process again.

In one example, the present disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

For example, the non-transitory computer readable storage medium may include a plurality of instructions, including those discussed above with regard to FIGS. 3A-7B, and/or instructions to control components of a processing system to perform the process of patterning a semiconductor device may include providing a stack of layers atop a substrate, the stack of layers comprising a dielectric film layer, and implanting the dielectric film layer with ions. The plurality of instructions may further include instructions to control components of the processing system to perform the process of depositing a metal oxide photoresist atop the dielectric film layer and exposing and patterning the metal oxide photoresist.

It is to be understood that the various layers, structures, and regions shown in the accompanying drawings are schematic illustrations. For ease of explanation, one or more layers, structures, and regions of a type commonly used to form semiconductor devices or structures may not be explicitly shown in a given drawing. This does not imply that any layers, structures, and/or regions not explicitly shown are omitted from the actual semiconductor structures.

For the sake of convenience and clarity, terms such as “top” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Further, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element, or intervening elements may also be present. In contrast, when an element is referred to as being “directly on,” “directly over” or “directly atop” another element, no intervening elements are present.

As used herein, “depositing” and/or “deposited” may include any now known or later developed techniques appropriate for the material to be deposited including yet not limited to, for example: chemical vapor deposition (CVD), low-pressure CVD (LPCVD), and plasma-enhanced CVD (PECVD). Additional techniques may include semi-atmosphere CVD (SACVD) and high-density plasma CVD (HDPCVD), rapid thermal CVD (RTCVD), ultra-high vacuum CVD (UHVCVD), limited reaction processing CVD (LRPCVD), metal-organic CVD (MOCVD), and sputtering deposition. Additional techniques may include ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

The various elements of the components as previously described with reference to FIGS. 1-7B may include various hardware elements, software elements, or a combination of both. Examples of hardware elements may include devices, logic devices, components, processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), memory units, logic gates, registers, semiconductor device, chips, microchips, chip sets, and so forth. Examples of software elements may include software components, programs, applications, computer programs, application programs, system programs, software development programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. However, determining whether an implementation is implemented using hardware elements and/or software elements may vary in accordance with any number of factors, such as desired computational rate, power levels, heat tolerances, dielectric materials used, processing cycle budget, input data rates, output data rates, memory resources, data bus speeds and other design or performance constraints, as desired for a given implementation.

One or more aspects of at least one implementation may be implemented by representative instructions stored on a machine-readable medium which represents various logic within the processor, which when read by a machine causes the machine to fabricate logic to perform the techniques described herein. Such representations, known as “IP cores”, may be stored on a tangible, machine readable medium and supplied to various customers or manufacturing facilities to load into the fabrication machines that make the logic or processor. Some implementations may be implemented, for example, using a machine-readable medium or article which may store an instruction or a set of instructions that, if executed by a machine, may cause the machine to perform a method and/or operations in accordance with the implementations. Such a machine may include, for example, any suitable processing platform, computing platform, computing device, processing device, computing system, processing system, computer, processor, or the like, and may be implemented using any suitable combination of hardware and/or software. The machine-readable medium or article may include, for example, any suitable type of memory unit, memory device, memory article, memory medium, storage device, storage article, storage medium and/or storage unit, for example, memory, removable or non-removable media, erasable or non-erasable media, writable or rewritable media, digital or analog media, hard disk, floppy disk, Compact Disk Read Only Memory (CD-ROM), Compact Disk Recordable (CD-R), Compact Disk Rewritable (CD-RW), optical disk, magnetic media, magneto-optical media, removable memory cards or disks, various types of Digital Versatile Disk (DVD), a tape, a cassette, or the like. The instructions may include any suitable type of code, such as source code, compiled code, interpreted code, executable code, static code, dynamic code, encrypted code, and the like, implemented using any suitable high-level, low-level, object-oriented, visual, compiled and/or interpreted programming language.

The components and features of the devices described above may be implemented using any combination of discrete circuitry, application specific integrated circuits (ASICs), logic gates and/or single chip architectures. Further, the features of the devices may be implemented using microcontrollers, programmable logic arrays and/or microprocessors or any combination of the foregoing where suitably appropriate. It is noted that hardware, firmware and/or software elements may be collectively or individually referred to herein as “logic” or “circuit.”

It will be appreciated that the exemplary devices shown in the block diagrams described above may represent one functionally descriptive example of many potential implementations. Accordingly, division, omission or inclusion of block functions depicted in the accompanying figures does not infer that the hardware components, circuits, software and/or elements for implementing these functions would necessarily be divided, omitted, or included in implementations.

At least one computer-readable storage medium may include instructions that, when executed, cause a system to perform any of the computer-implemented methods described herein.

Some implementations may be described using the expression “one implementation” or “an implementation” along with their derivatives. These terms mean that a particular feature, structure, or characteristic described in connection with the implementation is included in at least one implementation. The appearances of the phrase “in one implementation” in various places in the specification are not necessarily all referring to the same implementation. Moreover, unless otherwise noted the features described above are recognized to be usable together in any combination. Thus, any features discussed separately may be employed in combination with each other unless it is noted that the features are incompatible with each other.

It is emphasized that the Abstract of the Disclosure is provided to allow a reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single implementation for the purpose of streamlining the disclosure. This method of disclosure is not to be interpreted as reflecting an intention that the claimed implementations require more features than are expressly recited in each claim. Rather, as the following claims reflect, inventive subject matter lies in less than all features of a single disclosed implementation. Thus, the following claims are hereby incorporated into the Detailed Description, with each claim standing on its own as a separate implementation. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

What has been described above includes examples of the disclosed architecture. It is, of course, not possible to describe every conceivable combination of components and/or methodologies, but one of ordinary skill in the art may recognize that many further combinations and permutations are possible. Accordingly, the novel architecture is intended to embrace all such alterations, modifications and variations that fall within the spirit and scope of the appended claims.

The foregoing description of example implementations has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner and may generally include any set of one or more limitations as variously disclosed or otherwise demonstrated herein.

1. An ion beam implantation system, comprising:
a shutter component configured to adjust an ion beam received from an ion beam source and being incident on a wafer plane;
a controller component communicatively coupled to the shutter component, the controller is configured to
receive an ion beam implantation recipe; and
change a size of an aperture of the shutter component based the ion beam implantation recipe and one or more measurements of the ion beam.

2. The system of claim 1, wherein the ion beam implantation recipe includes a minimum size of the aperture.

3. The system of claim 2, wherein the shutter component includes a first aperture limiting portion and a second aperture limiting portion, the controller component is configured to cause the shutter component to
reduce the size of the aperture by moving the first and second aperture limiting portions closer together; or
increase the size of the aperture by moving the first and second aperture limiting portions apart from one another.

4. The system of claim 3, wherein the one or more measurements include a location of the ion beam on the wafer plane.

5. The system of claim 4, further comprising an electrostatic lens component and a dipole magnet component coupled to the controller component, wherein the controller component is configured to vertically center the ion beam on the wafer plane by
reducing, using the shutter component, the size of the aperture in accordance with the minimum size of the aperture; and
adjusting the ion beam by changing a vertical position of the ion beam to vertically center the ion beam on the wafer plane using at least one of: a Y-axis component of the electrostatic lens component, the dipole magnet component, and any combination thereof, wherein the changing of the vertical position is limited by the reduced size of the aperture;
wherein a vertical center of the ion beam on the wafer plane corresponds to a peak current of the ion beam generated in response to the adjusting performed by at least one of: the Y-axis component of the electrostatic lens component, the dipole magnet component, and any combination thereof.

6. The system of claim 5, wherein the Y-axis component of the electrostatic lens component and the dipole magnet component are configured to change the vertical position of the ion beam along a Y-direction of the ion beam by varying a respective position of the Y-axis component of the electrostatic lens component and a current of the dipole magnet component.

7. The system of claim 3, wherein the one or more measurements include a height of the ion beam on the wafer plane.

8. The system of claim 7, wherein adjusting the ion beam includes reducing the height of the ion beam on the wafer plane.

9. The system of claim 8, further comprising an electrostatic lens component coupled to the controller component, wherein the controller component is configured to reduce the height of the ion beam on the wafer plane by
reducing, using the shutter component, the size of the aperture in accordance with the minimum size of the aperture; and
adjusting the ion beam by changing the height of the ion beam along a Z-direction of the ion beam on the wafer plane using a Z-axis component of the electrostatic lens component, wherein the changing of the height of the ion beam along the Z-direction is limited by the reduced size of the aperture;
wherein the changed height of the ion beam along the Z-direction of the ion beam on the wafer plane corresponds to a peak current of the ion beam generated in response to the adjusting performed by the Z-axis component of the electrostatic lens component.

10. The system of claim 8, further comprising a focus voltage component coupled to the controller component, wherein the controller component is configured to reduce the height of the ion beam on the wafer plane by
reducing, using the shutter component, the size of the aperture in accordance with the minimum size of the aperture; and
adjusting the ion beam by changing the height of the ion beam by changing a focus voltage using the focus voltage component of the electrostatic lens component, wherein the changing of the height of the ion beam is limited by the reduced size of the aperture;
wherein the changed height of the ion beam on the wafer plane corresponds to a peak current of the ion beam generated in response to the adjusting performed by the focus voltage component of the electrostatic lens component.

11. The system of claim 8, further comprising a scan offset electrostatic lens component and a post scan offset electrostatic lens coupled to the controller component, wherein the controller component is configured to the reduce height of the ion beam on the wafer plane by
reducing, using the shutter component, the size of the aperture in accordance with the minimum size of the aperture; and
adjust the ion beam by changing the height of the ion beam on the wafer plane using at least one of: the scan offset electrostatic lens component, the post scan offset electrostatic lens, and any combination thereof, wherein the changing of the height of the ion beam is limited by the reduced size of the aperture;
wherein the height of the ion beam on the wafer plane corresponds to a peak current of the ion beam generated in response to the adjusting performed by at least one of: the scan offset electrostatic lens component, the post scan offset electrostatic lens, and any combination thereof.

12. The system of claim 7, wherein adjusting the ion beam includes increasing the height of the ion beam on the wafer plane.

13. The system of claim 12, further comprising a quadrupole magnet component coupled to the controller component, wherein the controller component is configured to increase the height of the ion beam on the wafer plane by
reducing, using the shutter component, the size of the aperture in accordance with the minimum size of the aperture; and
adjusting the ion beam by increasing the height of and reducing a width of the ion beam on the wafer plane using the quadrupole magnet component, wherein the increasing the height of and the reducing the width of the ion beam on the wafer plane is limited by the reduced size of the aperture;
wherein the increased height of the ion beam on the wafer plane corresponds to a peak current of the ion beam generated in response to the adjusting performed by the quadrupole magnet component.

14. A method, comprising:
receiving, using a controller component of an ion beam implantation system, an ion beam implantation recipe, the ion beam implantation system including an ion beam source configured to generate an ion beam, the ion beam being incident on a wafer plane, a shutter component, and the controller component communicatively coupled to the shutter component; and
changing, using the controller component, a size of an aperture of the shutter component based the ion beam implantation recipe and one or more measurements of the ion beam; and
adjusting, using the controller component, the ion beam received from the ion beam source.

15. The method of claim 14, wherein the ion beam implantation recipe includes a minimum size of the aperture.

16. The method of claim 15, wherein the shutter component includes a first aperture limiting portion and a second aperture limiting portion;
the method further comprising using the controller component to cause the shutter component to
reduce the size of the aperture by moving the first and second aperture limiting portions closer together; or
increase the size of the aperture by moving the first and second aperture limiting portions apart from one another.

17. The method of claim 16, wherein the one or more measurements include a location of the ion beam on the wafer plane.

18. The method of claim 17, wherein the ion beam implantation system includes an electrostatic lens component and a dipole magnet component coupled to the controller component;
the method further comprising vertically centering, using the controller component, the ion beam on the wafer plane by
reducing, using the shutter component, the size of the aperture in accordance with the minimum size of the aperture; and
adjusting the ion beam by changing a vertical position of the ion beam to vertically center the ion beam on the wafer plane using at least one of: a Y-axis component of the electrostatic lens component, the dipole magnet component, and any combination thereof, wherein the changing of the vertical position is limited by the reduced size of the aperture;
wherein a vertical center of the ion beam on the wafer plane corresponds to a peak current of the ion beam generated in response to the adjusting performed by at least one of: the Y-axis component of the electrostatic lens component, the dipole magnet component, and any combination thereof.

19. The method of claim 18, further comprising changing, using the electrostatic lens component and the dipole magnet component, the vertical position of the ion beam along a Y-direction of the ion beam by varying a respective position of the Y-axis component of the electrostatic lens component and a current of the dipole magnet component.

20. The method of claim 16, wherein the one or more measurements include a height of the ion beam on the wafer plane.

21. The method of claim 20, wherein adjusting the ion beam includes reducing the height of the ion beam on the wafer plane.

22. The method of claim 21, wherein the ion beam implantation system includes an electrostatic lens component coupled to the controller component;
the method further comprising reducing, using the controller component, the height of the ion beam on the wafer plane by
reducing, using the shutter component, the size of the aperture in accordance with the minimum size of the aperture; and
adjusting the ion beam by changing the height of the ion beam along a Z-direction of the ion beam on the wafer plane using a Z-axis component of the electrostatic lens component, wherein the changing of the height of the ion beam along the Z-direction is limited by the reduced size of the aperture;
wherein the changed height of the ion beam along the Z-direction of the ion beam on the wafer plane corresponds to a peak current of the ion beam generated in response to the adjusting performed by the Z-axis component of the electrostatic lens component.

23. The method of claim 21, wherein the ion beam implantation system includes a focus voltage component coupled to the controller component;
the method further comprising reducing, using the controller component, the height of the ion beam on the wafer plane by
reducing, using the shutter component, the size of the aperture in accordance with the minimum size of the aperture; and
adjusting the ion beam by changing the height of the ion beam by changing a focus voltage using the focus voltage component of the electrostatic lens component, wherein the changing of the height of the ion beam is limited by the reduced size of the aperture;
wherein the changed height of the ion beam on the wafer plane corresponds to a peak current of the ion beam generated in response to the adjusting performed by the focus voltage component of the electrostatic lens component.

24. The method of claim 21, wherein the ion beam implantation system includes a scan offset electrostatic lens component and a post scan offset electrostatic lens coupled to the controller component;
the method further comprising reducing, using the controller component, the height of the ion beam on the wafer plane by
reducing, using the shutter component, the size of the aperture in accordance with the minimum size of the aperture; and
adjust the ion beam by changing the height of the ion beam on the wafer plane using at least one of: the scan offset electrostatic lens component, the post scan offset electrostatic lens, and any combination thereof, wherein the changing of the height of the ion beam is limited by the reduced size of the aperture;
wherein the height of the ion beam on the wafer plane corresponds to a peak current of the ion beam generated in response to the adjusting performed by at least one of: the scan offset electrostatic lens component, the post scan offset electrostatic lens, and any combination thereof.

25. The method of claim 20, wherein adjusting the ion beam includes increasing the height of the ion beam on the wafer plane.

26. The method of claim 25, wherein the ion beam implantation system includes a quadrupole magnet component coupled to the controller component;
the method further comprising increasing, using the controller component, the height of the ion beam on the wafer plane by
reducing, using the shutter component, the size of the aperture in accordance with the minimum size of the aperture; and
adjusting the ion beam by increasing the height of and reducing a width of the ion beam on the wafer plane using the quadrupole magnet component, wherein the increasing the height of and the reducing the width of the ion beam on the wafer plane is limited by the reduced size of the aperture;
wherein the increased height of the ion beam on the wafer plane corresponds to a peak current of the ion beam generated in response to the adjusting performed by the quadrupole magnet component.
